(19) United States
(12) Patent Application Publication
(10) Pub. No.: US 2010/0139748 A1
(43) Pub. Date: Jun. 10, 2010

(54) SOLAR CELL HAVING EUROPIUM-DOPED COVER GLASS

(75) Inventor: YUAN-CHIEH DING, Tucheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/606,264

(22) Filed: Oct. 27, 2009

(30) Foreign Application Priority Data
Dec. 8, 2008 (CN) 200810306025.9

(51) Int. Cl. H01L 31/00

(52) U.S. Cl. 136/255

(57) ABSTRACT

A solar cell includes a photoelectric conversion module having a light incident surface and a europium-doped cover glass applied on the light incident surface. The photoelectric conversion module is configured for receiving light and converting the light into electric energy. The cover glass includes two phases each having a phase size of less than 500 nanometers. At least one of the phases is interconnected three-dimensionally throughout the cover glass. The cover glass being capable of converting first light of a first wavelength into second light of a second wavelength, the second wavelength is greater than the first wavelength.

### BACKGROUND

1. Technical Field

The present invention relates generally to a solar cell, especially to a solar cell having a europium-doped (Eu-doped) cover glass.

2. Description of Related Art

One of the factors limiting the efficiency of solar cells is the light conversion rate of photoelectric material (such as cadmium telluride based and silicon-based photoelectric material). Generally, these photoelectric materials can absorb only light in wavelengths from 400 nanometers (nm) to 1100 nm for conversion into electric energy. That is, light outside this range is unutilized.

Therefore, what is needed is to provide a solar cell which is capable of overcoming the aforementioned problems.

### BRIEF DESCRIPTION OF THE DRAWINGS

Many aspects of the present solar cell can be better understood with references to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic view of a solar cell includes a photoelectric conversion module and a Eu-doped cover glass in accordance with the disclosure.

FIG. 2 shows a microstructure of the Eu-doped cover glass of FIG. 1.

FIG. 3 shows scanning electron microscope (SEM) images of cover glass samples (a)-(e) doped with different molar ratio of Eu after annealed at 650° C. for 12 hours, wherein each sample has a borate-rich phase with a bright contrast and a silica-rich phase with a dark contrast.

FIG. 4 shows phase size of the silica-rich phase of the Eu-doped cover glass samples (a)-(e) of FIG. 3.

FIG. 5 shows relationship between phase size of silica-rich phase of sample (b) and annealing time at 570° C. and relationship between phase size of silica-rich phase of sample (d) and annealing time at 650° C.

FIG. 6 shows absorption spectrum of samples (b) after annealed at 650° C. for 0 minute, 20 minutes, and 40 minutes, respectively.

FIG. 7 shows excitation spectrum under 465 nm excitation of samples (b) after annealed at 650° C. for 0 minute, 20 minutes, 40 minutes, 60 minutes, and 210 minutes, respectively.

FIG. 8 shows relationship between annealing time at 650° C. and excitation spectrum intensity at a wavelength of 615 nm in sample (a).

FIG. 9 shows relationship between annealing time at 650° C. and emission spectrum intensity at a wavelength of 615 nm in sample (b).

FIG. 10 shows relationship between annealing time at 650° C. and emission spectrum intensity at a wavelength of 615 nm in sample (c).

FIG. 11 shows relationship between annealing time at 650° C. and emission spectrum intensity at a wavelength of 615 nm in sample (d).

FIG. 12 shows relationship between annealing time at 650° C. and emission spectrum intensity at a wavelength of 615 nm in sample (e).

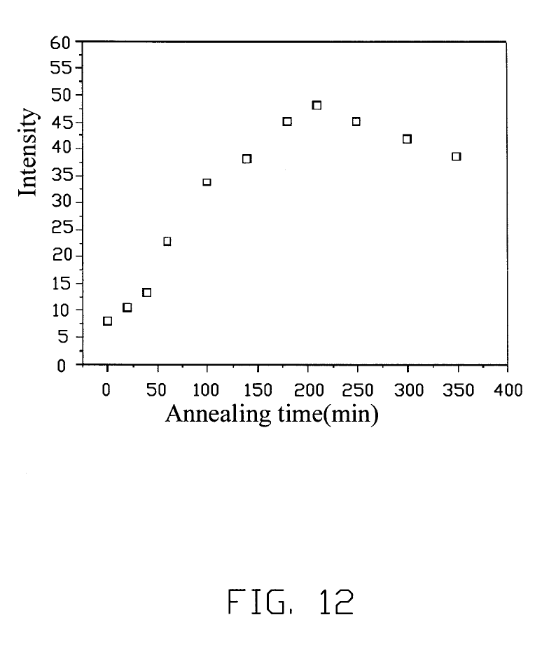

### DETAILED DESCRIPTION

Embodiments of a solar cell will be described in detail with reference to the accompanying drawings.

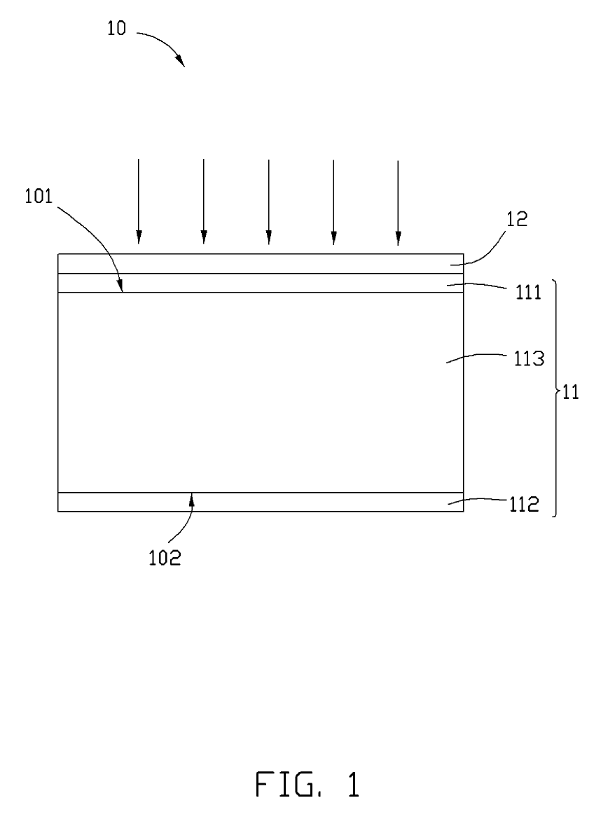

Referring to FIG. 1, a solar cell 10 in accordance with the disclosure includes a photoelectric conversion module 11 and a Eu-doped cover glass 12 arranged on the photoelectric conversion module 11. The cover glass 12 is configured for converting first light of a first wavelength into second light of a second wavelength.

The photoelectric conversion module 11 includes a front electrode 111, a back electrode 112, and a photoelectric layer 113 sandwiched therebetween. The photoelectric layer 113 has a top surface 101 defined as a light incident surface and a bottom surface 102 opposite to the top surface 101. The front electrode 111 is arranged between and in contact with the cover glass 12 and the top surface 101. The back electrode 112 is in contact with the bottom surface 102.

In the present embodiment, the front electrode 111 is a transparent conductive layer. When light irradiates on the solar cell 10; it passes through the cover glass 12 and the front electrode 111 first, and then enters the photoelectric layer 113. The photoelectric layer 113 receives the light and converts it to electric energy. The front electrode 111 and the back electrode 112 are electronically connected to one or more external loads, thereby transmitting electric energy generated in the photoelectric layer 113 of the solar cell 10 to the external loads. The transparent conductive layer is comprised of a transparent conductive material (such as indium tin oxide). In other embodiments, the transparent conductive layer can include a transparent substrate (such as a glass substrate) with a transparent film deposited thereon. Examples of transparent film include film of cadmium oxide (CdO), zinc oxide (ZnO), binary oxides of zinc which have a formula of ZnO:M, wherein M represents aluminum (Al), gallium (Ge), indium (In), and fluorine (F). The back electrode 112 is metal such as aluminum or copper). The photoelectric layer 113 is a silicon-based semiconductor, group III-V semiconductor, or group II-VI semiconductor.

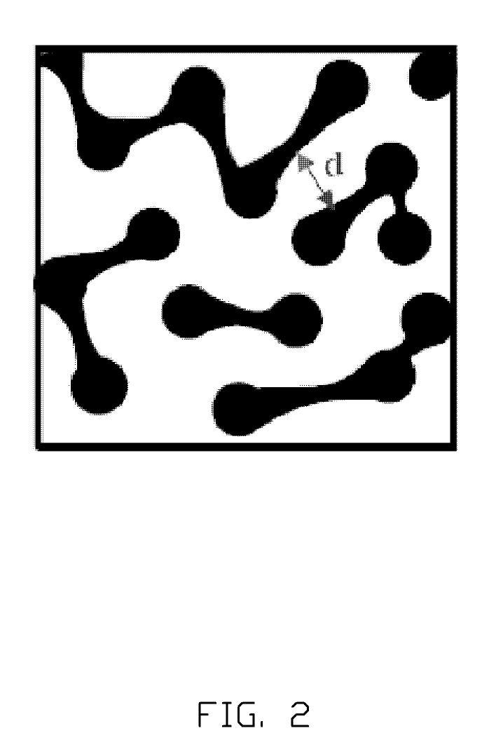

The cover glass 12 contains europium (Eu) or europium-containing compound therein. The cover glass 12 is capable of absorbing light of a wavelength range of 362-577 nanometers (nm) and emitting light of a wavelength range of 579-700 nm. In other words, the cover glass 12 can absorb ultraviolet light and emit visible light. As shown in FIG. 2, the cover glass 12 includes two phases, with at least one of the two phases being continuous/interconnected three-dimensionally throughout the whole cover glass 12. Phase size of each phase is less than 500 nm. It is understood that the two phases have irregular shapes and the phase size is represented by an average distance d between two adjacent portions in one phase and separated by a portion of the other phase. Phase boundaries of the two phases can refract and reflect light to Eu or europium-containing compound contained in the two phases, and Eu or europium-containing compound is capable of converting light of a wavelength of 362-577 nanometers (nm) and emitting light of a wavelength range of 579-700 nm.

The cover glass 12 is manufactured by heat treatment a glass doped with Eu or Eu-containing compound to perform spinodal decomposition at a temperature between a glass transition temperature (Tg) and a crystallization temperature (Tc) thereof. In this temperature range, the cover glass 12 can maintain its crystalline structure and thus is still transparent after the heat treatment step, but the most appropriate temperature for the heat treatment step varies according to the required phase size. Generally, the higher the temperature is, the more energy is supplied to the glass and the spinodal decomposition is performed under a high rate. The phases continue to grow under this temperature. As a result, the phase size may exceed 500 nm and transparence of the obtained cover glass 12 is low. In contrast, if the heating temperature is at a low level, such as close to Tg, the spinodal decomposition is performed at a lower rate. Thus, a longer reaction time is required to obtain appropriate phase size.

As described, the phase boundaries of the two phases can refract and reflect light to Eu or europium-containing compound contained in the two phases, thereby improving light conversion efficiency. However, if the phase size of each phase in cover glass 12 is greater than 500 nm, the converted light is easily refracted or reflected at the phase boundaries. As a result, most of the converted light is absorbed by the cover glass 12 when the light passes through. In contrast, if the phase size of each phase is less than 500 nm, most of the converted light can pass through the cover glass 12. In this situation, the refraction and reflection at the phase boundaries slight affect the total transparence of the cover glass 12.

The cover glass 12 can be comprised of a borosilicate glass doped with Eu or europium-containing compound. The borosilicate glass is comprised of silicon dioxide (SiO₂), boron oxide (B₂O₃), and oxides of alkali metals (such as sodium oxide (Na₂O)). In the present embodiment, the cover glass 12 substantially consists of SiO₂, B₂O₃, Na₂O, and Eu₂O₃. Eu₂O₃ is an electrovalent type covalent oxide, whereby the Eu in Eu₂O₃ tends to lose its three outermost electrons and therefore has similar properties to Eu³⁺ ions. In other words, Eu also exists in the silicate glass in the form of Eu³⁺ ions. A molar ratio of Eu to all compounds in the borosilicate glass (such as the sum of SiO₂, B₂O₃, and Na₂O) is less than 5%. In other embodiments, the molar ratio can be less than 2.5%. One phase in the cover glass 12 is borate-rich phase, and the other phase in the cover glass 12 is silica-rich phase. Eu is distributed in both of the borate-rich phase and silica-rich phase. In particular, more than half of Eu is gathered in the borate-rich phase.

In the present embodiment, the cover glass 12 has a composition can be represented by the molecular formula 59SiO₂-33B₂O₃-8Na₂O-xEu₂O₃, wherein x is in the range from 0.5 to 2.5. That is, a molar ratio of Eu₂O₃ to the sum of SiO₂, B₂O₃, and Na₂O is from 0.5% to 2.5%, and a molar ratio of Eu to the sum of SiO₂, B₂O₃, and Na₂O is from 1% to 5%. In a process of synthesizing the composition, the mixture of SiO₂, H₃BO₃, Na₂CO₃, and Eu₂O₃ is placed in a platinum crucible and then heated to increase the temperature of the mixture at a speed of 10° C. per minutes. After the temperature of the mixture reaches a point from approximately 1400° C. to approximately 1500° C., the temperature is maintained for approximately 30 minutes thereby obtaining a melted mixture. The melted mixture is poured into a mold and fast cooled to obtain the cover glass 12. An additional annealing process at a temperature between 570° C. (Tg) and 750° C. (Tc) is employed to reduce inner stress in the cover glass 12.

To test performance of cover glass 12 containing different contents of Eu₂O₃, five cover glass samples (a)-(e), as listed in table 1, were prepared and then tested.

TABLE 1
composition of the cover glass samples

| | |
|---|---|
| Cover glass | Composition (molar ratio) |

| samples | SiO₂ | B₂O₃ | Na₂O | Eu₂O₃ |
|---|---|---|---|---|
| (a) | 56.05 | 35.79 | 8.16 | 0.27 |
| (b) | 56.18 | 35.61 | 8.21 | 0.85 |
| (c) | 56.84 | 35.00 | 8.16 | 1.00 |
| (d) | 57.02 | 34.87 | 8.11 | 1.11 |
| (e) | 56.68 | 35.12 | 8.2 | 2.47 |

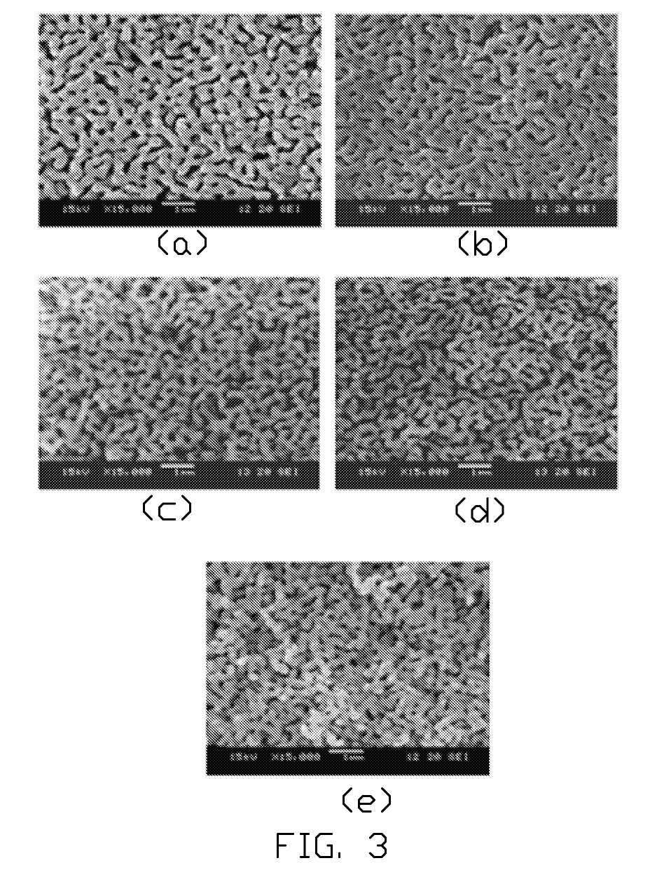

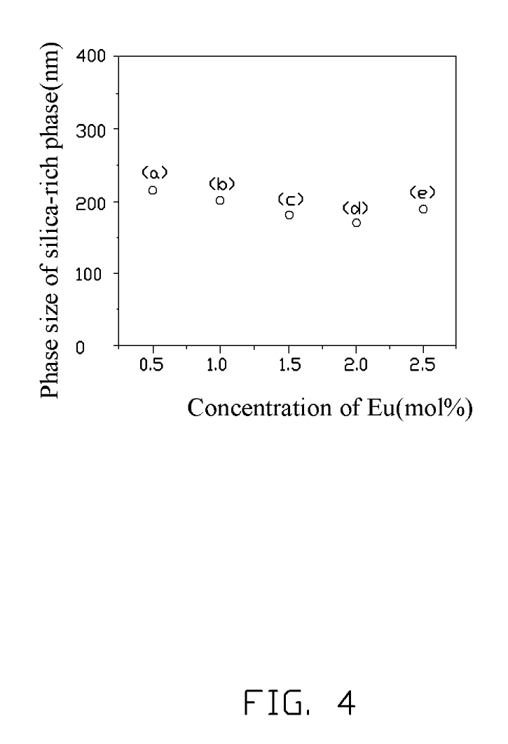

FIG. 3 shows scanning electron microscope (SEM) images of the samples (a)-(e) after being annealed at 650° C. for 12 hours. Each sample has a borate-rich phase with a bright contrast and a silica-rich phase with a dark contrast. Most of Eu₂O₃ exists in the borate-rich phase. FIG. 4 illustrates phase size of the silica-rich phase of the samples (a)-(e) is from approximately 160 nm to approximately 230 nm.

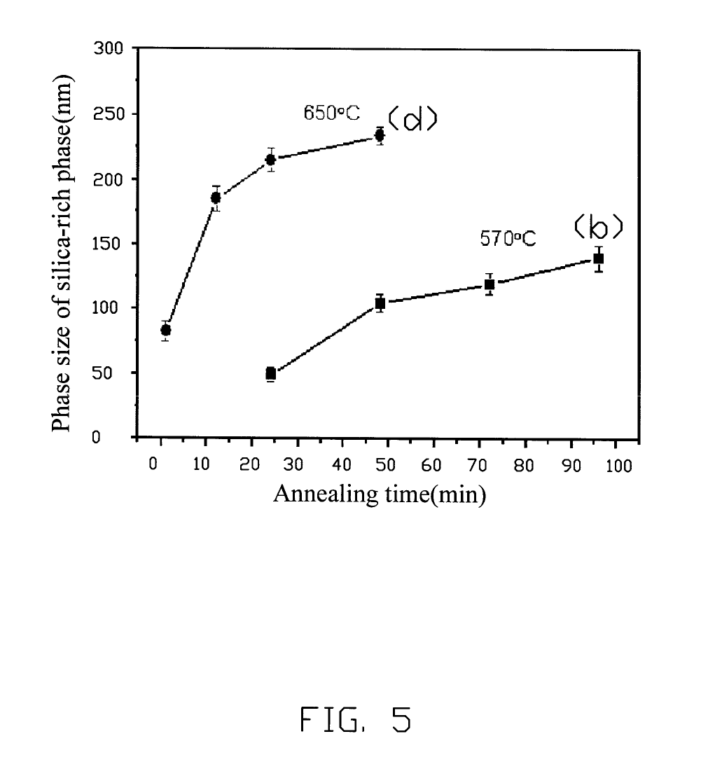

As shown in FIG. 5, phase size of the silica-rich phase of the cover glass 12 increases with the annealing time, and further with the concentration of Eu₂O₃. The phase size of the silica-rich phase of the glass sample (b) is less than 150 nm if it was annealed at 570° C. less than 100 hours. The phase size of the silica-rich phase of the glass sample (d) is less than 250 nm if it was annealed at 650° C. less than 50 hours. Irrespective of the concentration of the Eu₂O₃ (in the molar range from 0.5 to 2.5), the phase size of the silica-rich phase and borate-rich phase of the samples can be controlled by the annealing time. If the phase size of each of the silica-rich phase and borate-rich phase is less than 100 nm, the glass sample has a high light conversion efficiency. For glass sample (d), if the annealing time is less than 210 minutes, and the annealing temperature is less than 650° C., the phase size thereof is less than 100 nm.

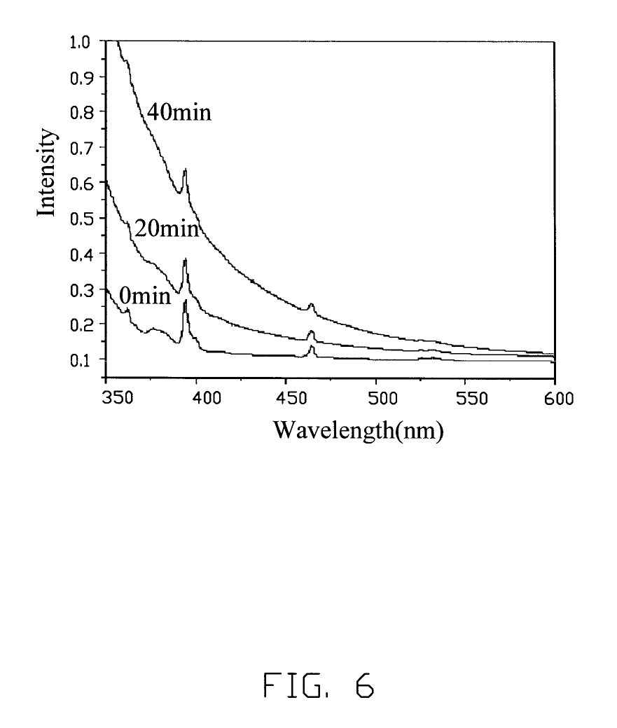

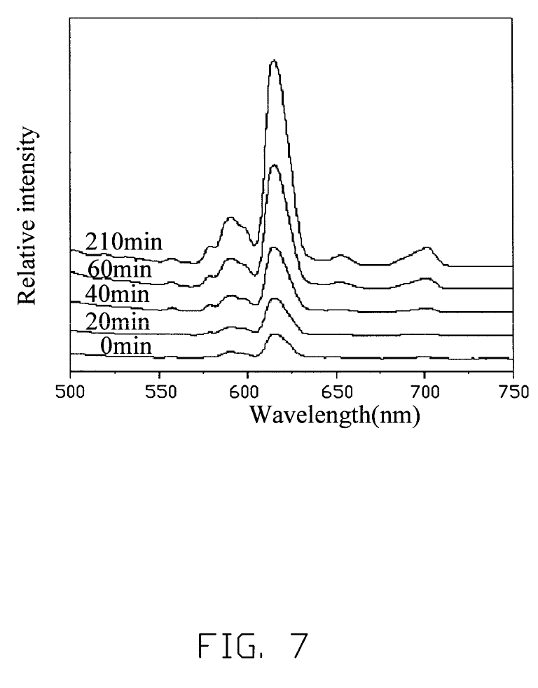

FIG. 6 illustrates ultraviolet absorption spectrum of samples (b) annealed at 650° C. for different times, in which absorption peaks appear at 577 nm, 531 nm, 525 nm, 465 nm, 415 nm, 394 nm, 378 nm, and 362 nm. FIG. 7 illustrates fluorescence excitation spectrum under 465 nm excitation of samples (b) annealed at 650° C. for different times, in which emission peaks appear at 579 nm, 590 nm, 615 nm, 650 nm, and 700 nm. Similar results are also observed using excitation of other wavelength (for example, 362 nm, 378 nm, 394 nm, 415 nm). These indicate that the sample (b) is capable of converting light in a wavelength range of 362-577 nm into light in a wavelength range of 579-700 nm, which can be utilized by the photoelectric layer 113. As such, the light utilizing efficiency of the solar cell 10 is improved. Other cover glass samples demonstrate similar properties, but the ultraviolet visible absorption spectrums and the fluorescence spectrums are not shown for concision purposes.

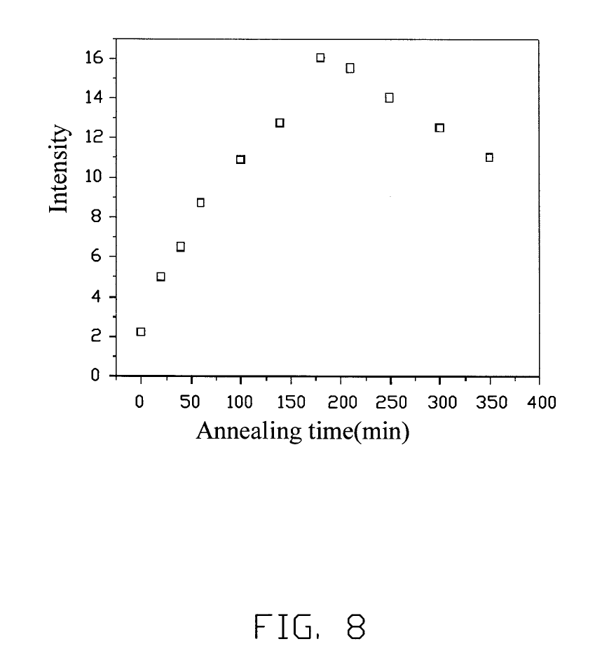

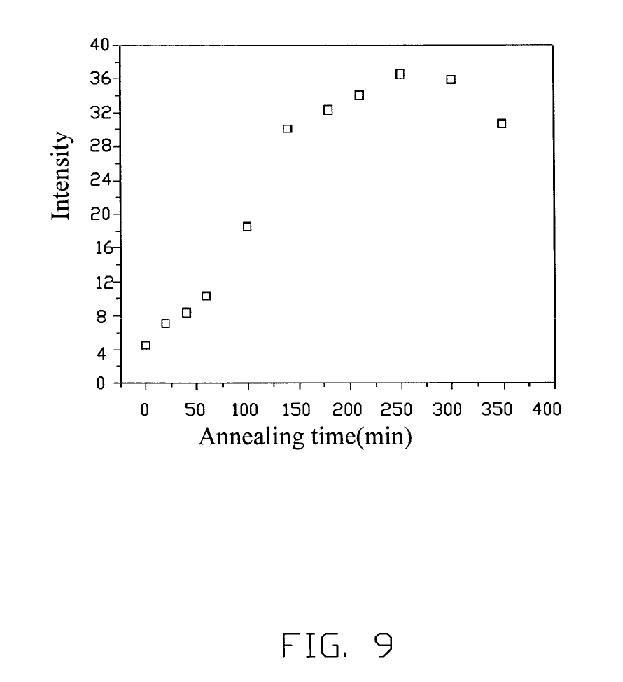

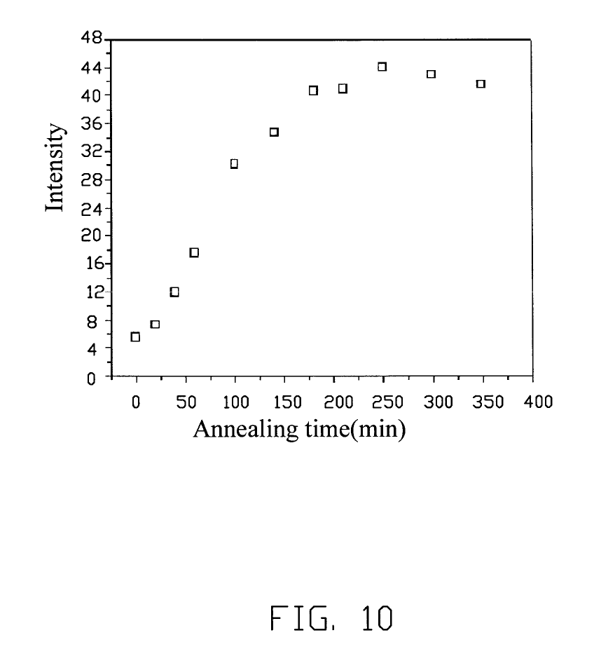

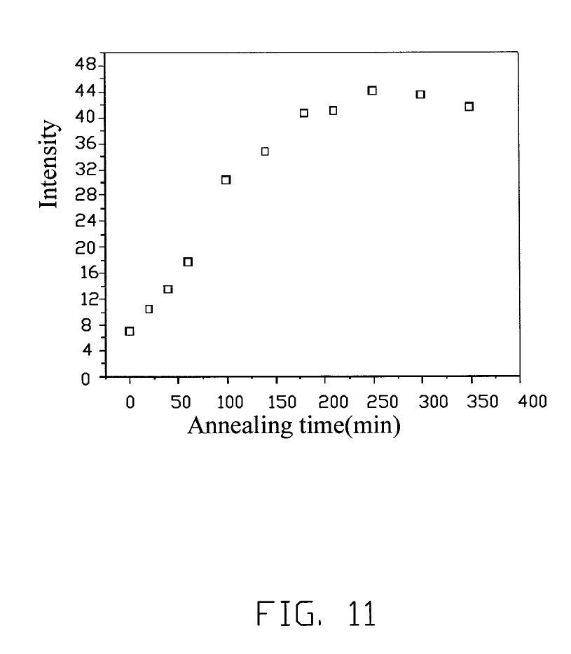

FIGS. 7 through 11 respectively illustrate relationship between annealing time at 650° C. and excitation spectrum intensity at a wavelength of 615 nm, in the samples (a)-(e). It is shown that after a certain annealing time, the excitation intensity of the samples at a wavelength of 615 nm peaks and begins to decrease, and the certain annealing time of the samples (a)-(e) is 180 minutes, 250 minutes, 245 minutes, 240 minutes, and 210 minutes respectively. In other words, the cover glass 12 can be annealed at 650° C. for less than 250 minutes, and more preferably, less than 180 minutes.

While certain embodiments have been described and exemplified above, various other embodiments from the foregoing disclosure will be apparent to those skilled in the art. The present invention is not limited to the particular embodiments described and exemplified but is capable of considerable variation and modification without departure from the scope of the appended claims.

1. A solar cell, comprising:
a photoelectric conversion module for receiving light and converting the light into electric energy, the photoelectric conversion module having a light incident surface; and
a europium-doped cover glass applied on the light incident surface, the cover glass being capable of converting first light of a first wavelength into second light of a second wavelength, the second wavelength being greater than the first wavelength, the cover glass comprising two phases each having a phase size of less than 500 nanometers, at least one of the phases being interconnected three-dimensionally throughout the cover glass.

2. The solar cell of claim 1, wherein both of the phases are interconnected three-dimensionally throughout the cover glass.

3. The solar cell of claim 1, wherein each phase has a phase size of less than 100 nanometers.

4. The solar cell of claim 1, wherein one of the phases is a silica-rich phase, the other of the phases is a borate-rich phase, and more than half of the europium is distributed in the borate-rich phase.

5. The solar cell of claim 1, wherein the cover glass comprises europium oxide, and a molar ratio of the europium oxide to remaining compounds in the cover glass is less than or equal to 2.5%.

6. The solar cell of claim 1, wherein the cover glass substantially consists of silicon oxide, boron oxide, alkali metal oxide, and europium oxide.

7. The solar cell of claim 1, wherein the solar cell comprises a front electrode, a back electrode, and a photoelectric layer sandwiched between the first electrode and the back electrode, the light incident surface is a surface of the photoelectric layer adjacent to the front electrode, and the front electrode is arranged between the cover glass and the photoelectric layer.

8. The solar cell of claim 7, wherein the front electrode is comprised of a transparent conductive layer sandwiched between and in contact with the light incident surface of the photoelectric layer and the cover glass.

9. The solar cell of claim 1, wherein the cover glass is represented by a molecular formula 59SiO₂-33B₂O₃-8Na₂O-xEu₂O₃, wherein x is in the range from 0.5 to 2.5.

10. The solar cell of claim 1, wherein a molar ratio of europium to remaining compounds in the cover glass is less than 5%.

11. The solar cell of claim 1, wherein a molar ratio of europium to remaining compounds in the cover glass is less than 2.5%.

12. A solar cell, comprising:
a photoelectric conversion module for receiving light and converting the light into electric energy, the photoelectric conversion module having a light incident surface; and
a europium-doped cover glass arranged on the light incident surface, the cover glass being capable of converting light of a wavelength of 362-577 nanometers to light of a wavelength of 579-700 nm and transmitting the converted light to the light incident surface, the cover glass consisting of two phases each having a phase size of less than 500 nanometers, at least one of the phases being interconnected three-dimensionally throughout the cover glass.

13. The solar cell of claim 12, wherein the cover glass substantially consists of silicon oxide, boron oxide, alkali metal oxide, and europium oxide.
